(19) United States
(12) Patent Application Publication
(10) Pub. No.: US 2024/0202387 A1
(43) Pub. Date: Jun. 20, 2024

(54) DETECTING X STATE TRANSITIONS BY MONITORING A SUBSET OF SIGNALS DETERMINED BASED ON A DEVICE STATE

(71) Applicant: INTERNATIONAL BUSINESS MACHINES CORPORATION, ARMONK, NY (US)

(72) Inventors: PRETTY MARIAM JACOB, BANGALORE (IN); SWATHI PRIYA S, BANGALORE (IN); SANDEEP KORRAPATI, BANGALORE (IN); ANUSHA REDDY RANGAREDDYGARI, BANGALORE (IN); PULI SRIVANI, HYDERABAD (IN); SREEKANTH REDDY KADAPALA, BANGALORE (IN)

(21) Appl. No.: 18/066,665

(22) Filed: Dec. 15, 2022

(51) Int. Cl. G06F 30/20

(52) U.S. Cl. CPC G06F 30/20

(57) ABSTRACT

A method for identifying a transition of a signal from a defined state to an undefined state when simulating a device includes. Storing a set of breakpoints, each breakpoint associated with a state of the device and identifying a set of signals from the device. A simulation of the device is executed using simulation, and a current state of the device is determined from values of one or more storage elements of the device. A breakpoint list including one or more breakpoints is selected based on the current state of the device. The set of signals from the device identified by the one or more breakpoints included in the breakpoint list is monitored.

### BACKGROUND

### Field of the Invention

The field of the invention is data processing, or, more specifically, methods, apparatus, and products for debugging in a digital simulation environment.

### Description of Related Art

The development of the EDVAC computer system of 1948 is often cited as the beginning of the computer era. Since that time, computer systems have evolved into extremely complicated devices. Today's computers are much more sophisticated than early systems such as the EDVAC. Computer systems typically include a combination of hardware and software components, application programs, operating systems, processors, buses, memory, input/output devices, and so on. As advances in semiconductor processing and computer architecture push the performance of the computer higher and higher, more sophisticated computer software has evolved to take advantage of the higher performance of the hardware, resulting in computer systems today that are much more powerful than just a few years ago.

An uninitialized logic or undefined value at an input of a hardware device, such as a processor or other chip, may drive multiple latches of the hardware device into an undefined state. To identify latches driven to an undefined state, multi-valued simulators are run using a digital simulator. For example, a hardware description language representation of a hardware device is converted to a multi-value simulation model. A test case is run using the multi-value simulation model until an X state failure is detected by a checker. An X state failure is defined as a transition from a defined value to an undefined value in a multi-value simulation.

In conventional testing, all signals in the HDL representation of the hardware device are monitored during testing. For example, a waveform is generated for all signals during testing. When a transition from a defined value to an undefined value (i.e., an X state failure) is detected, captured data describing various signals, such as signal waveforms, are reviewed to identify a cause for the X state failure. Additionally, multiple iterations of a test may be performed to identify a cause of an X state failure that was detected later than when the cause of the X state failure occurred. Performing multiple iterations of a test results in consuming a significant amount of time for the multiple iterations and in consuming significant storage resources for storing data describing the signals monitored during testing.

### SUMMARY

Methods and systems for identifying a transition of a signal from a defined state to an undefined state when simulating a device includes. Storing a set of breakpoints, each breakpoint associated with a state of the device and identifying a set of signals from the device. A simulation of the device is executed using simulation, and a current state of the device is determined from values of one or more storage elements of the device. A breakpoint list including one or more breakpoints is selected based on the current state of the device. The set of signals from the device identified by the one or more breakpoints included in the breakpoint list is monitored.

The foregoing and other objects, features and advantages of the disclosure will be apparent from the following more particular descriptions of exemplary embodiments of the disclosure as illustrated in the accompanying drawings wherein like reference numbers generally represent like parts of exemplary embodiments of the disclosure.

### BRIEF DESCRIPTION OF THE DRAWINGS

FIG. 1 is a block diagram of an example computing environment, according to some embodiments of the present disclosure.

FIG. 2 is a block diagram of a testing module, according to some embodiments of the present disclosure.

FIG. 3 is a process flow diagram of selecting a breakpoint list for monitoring a device being tested, according to some embodiments of the present disclosure.

FIG. 4 is a flowchart of a method for detecting an X state failure when simulating a device, according to some embodiments of the present disclosure.

### DETAILED DESCRIPTION

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

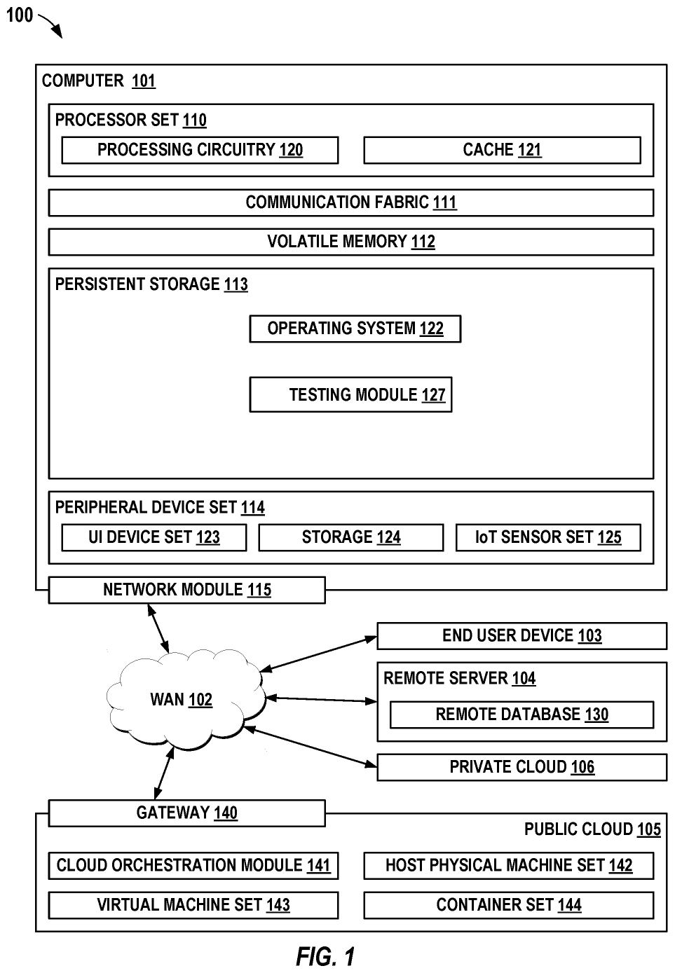

Computing environment 100 shown in FIG. 1 contains an example of an environment for the execution of at least some of the computer code involved in performing the inventive methods, such as testing module 127. In addition to testing module 127, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and testing module 127, as identified above), peripheral device set 114 (including user interface (UI) device set 123, storage 124, and Internet of Things (IOT) sensor set 125), and network module 115. Remote server 104 includes remote database 130. Public cloud 105 includes gateway 140, cloud orchestration module 141, host physical machine set 142, virtual machine set 143, and container set 144. Computing environment 100 contains an example of an environment for the execution of at least some of the computer code involved in performing the inventive methods, such as the testing module 127. The testing module 127 includes instructions and data for simulating operation of devices, such as a computer processor. The instructions included in the testing module 127 correspond to various operating tasks or functions of a device, and the testing module 127 provides instructions to the device (e.g., to a computer processor) to test or to evaluate capability of the device to perform different operating tasks or functions. In addition to testing module 127, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and testing module 127, as identified above), peripheral device set 114 (including user interface (UI) device set 123, storage 124, and Internet of Things (IOT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in the testing module 127 in persistent storage 113.

Communication fabric 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in the testing module 127 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

Wide area network (WAN) 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

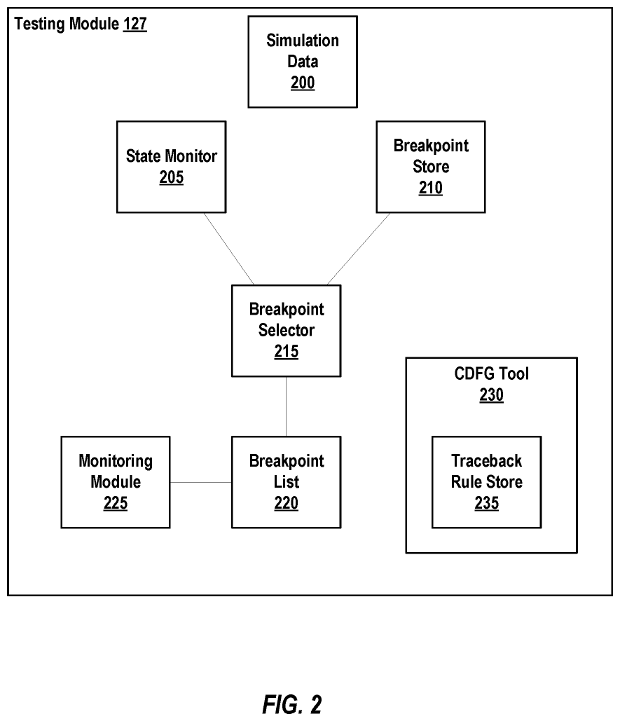

For further illustration, FIG. 2 is a block diagram of an example embodiment of a testing module 127. The testing module 127 can include one or more modules or components. Components or modules comprising the testing module 127 may be an application specific integrated circuit (ASIC), an electronic circuit, a processor (shared, dedicated, or group) and/or memory that executes one or more software or firmware programs, a combinational logic circuit, and/or other suitable components that provide the described functionality. As can be appreciated, the modules shown can be combined and/or further partitioned in different embodiments. In the example of FIG. 2, the testing module 127 includes simulation data 200, a state monitor 205, a breakpoint store 210, a breakpoint selector 215, a breakpoint list 220, a monitoring module 225, and a control data flow graph (CDFG) tool 230. However, in other embodiments, the testing module 127 may include different or additional modules than those described in conjunction with FIG. 2.

The simulation data 200 describes one or more a multi-valued simulations in various embodiments. In various embodiments, the simulation data 200 includes data or instructions for communication to a device, such as a processor, being tested. The data or instructions causes the device to perform operations corresponding to certain operation. In various embodiments, a simulation is based on one or more models and simulates operation of the device. For example, a simulation simulates a sequence of actions performed by the device when the device is initially powered on. In an example, the simulation provides a sequence of actions performed by a processor when the processor is initially powered on. Different simulations simulate different steps in initializing the device in various embodiments. Further, different simulations simulate different operations of the device. The simulation data 200 includes data describing one simulation in some embodiments, while in other embodiments the simulation data 200 includes data describing multiple simulations, allowing selection of a specific simulation from the simulation data.

The state monitor 205 is coupled to a device being tested to identify an X state failure, which is a transition from a defined value to an undefined value in a multi-value simulation. The state monitor 205 receives data from the device identifying values of one or more latches or registers of the device being tested. For example, the state monitor 205 receives values of a set of latches, with the combination of values for the set of latches representing the state of the device being tested. In some embodiments, the state monitor 205 determines a state of the device being tested as a combination of values in one or more latches or registers of the device being tested. In other embodiments, the state monitor 205 maps a combination of values in one or more latches or registers of the device being tested to a predefined state.

The breakpoint store 210 stores a set of breakpoints, with each breakpoint associated with at least one state. A breakpoint identifies a set of signals from the device being tested to be monitored. For example, a breakpoint identifies a set of specific latches, specific registers, or other specific components of the device being tested that are monitored during simulation of operation of the device being tested for an X state. In various embodiments, the set of signals is less than a complete set of signals produced by the device being tested. While conventional testing methods monitor all signals of the device being tested, the breakpoint store 210 allows the testing module 127 to monitor a specific set of signals for an X state, reducing a number of signals that are monitored and analyzed.

As different sets of signals have different likelihoods of producing an X state failure at different points in a simulation, by storing different breakpoints that are associated with different states of the device being tested, the breakpoint store 210 allows different signals to be monitored when the device being tested is in different states. Having a set with different breakpoints corresponding to different states of the device being tested allows different sets of signals to be monitored at different times by selecting one or more breakpoints based on a state of the device being tested (e.g., values of registers or latches of the device being tested). As a breakpoint identifies less than the complete set of signals of the device being tested, selecting a breakpoint reduces a number of signals of the device being tested that are monitored to those identified by the selected breakpoint. This reduces an amount of data that is analyzed to determine whether an X state failure occurred.

In various embodiments, the breakpoints in the breakpoint store 210 are defined before testing begins on a device. The signals included in a breakpoint are determined based on prior testing of devices, characteristics of the device, prior testing of the device being tested, or other information. In various embodiments, one or more users specify the breakpoints by identifying a state of the device under test and one or more signals to monitor that are associated with the state. The one or more signals are stored in association with the state of the device in the breakpoint store 210. In some embodiments, information identifying the device under test is also stored in association with the state of the device.

The breakpoint selector 215 selects a breakpoint list 220 from the breakpoint store 210 based on a state of the device being tested from the state monitor 205. In various embodiments, the breakpoint selector 215 selects one or more breakpoints from the breakpoint store 210 that are associated with a state of the device being tested determined by the state monitor 205. The selected breakpoints comprise the breakpoint list 220. For example, the breakpoint list 220 includes each breakpoint from the breakpoint store 210 that is associated with a state of the device being tested matching a state of the device being tested determined by the state monitor 205. The breakpoint selector 215 dynamically selects the breakpoint list 220, so the breakpoint list 220 changes as a state of the device being tested changes. As a breakpoint identifies a set of signals from the device being tested that are monitored, changing the breakpoint list 220 changes the set of signals from the device being tested that are monitored. This allows the number of signals being monitored to be less than the complete set of signals from the device being monitored, while monitoring the signals from the device being tested most likely to produce an X state failure. Thus, the breakpoint selector 215 enables more efficient monitoring of signals from the device being tested by accounting for different states of the device being tested.

The monitoring module 225 obtains the breakpoint list 220 and captures data from the set of signals identified by the breakpoint list 220 from the device being tested. As the breakpoint list 220 is modified, the set of signals monitored by the monitoring module 225 changes. The monitoring module 225 determines whether a signal being monitored includes an X state failure, where the signal transitions from a defined value to an undefined value. In response to detecting an X state failure on a signal being monitored, the monitoring module 225 suspends a simulation used to test the device being tested. In contrast, conventional methods for X state testing identify occurrence of an X state failure, while a simulation used to test the device being tested continues to run.

Additionally, in response to the monitoring module 225 detecting an X state failure on a signal being monitored, a control and data-flow graph (CDFG) tool 230 is triggered to identify a source of the X state failure that was detected. The CDFG tool 230 describes control and data flow information through the simulation being performed to test the device being tested. For example, the CDFG tool 230 generates or obtains a flow-graph or a netlist representation of the simulation applied to the device being tested that describes data dependencies and control dependencies between different registers of a device. When the monitoring module 225 detects an X state failure and suspends simulation, the CDFG tool 230 traces the flow-graph or netlist representation of the simulation back from a time when the X state failure was detected to identify signals related to the X state failure and to identify a signal that caused the X state failure by back traversing the flow-graph or netlist representation of the simulation. The CDFG tool 230 obtains a logical cone of influence for the X state failure by back-traversing the netlist or flow-graph representation of the simulation. The logical cone of influence includes a listing of signals that are related to the signal for which the X state failure was detected. Signals in the logical cone of influence are signals that are related to or that influence a value of the signal for which the X state failure was detected. As the breakpoint list 220 specified a set of signals of the device being tested that are monitored, the amount of the flow-graph or netlist representation of the simulation that is back-traversed by the CDFG tool 230 is reduced compared to conventional techniques for X state testing.

From the logical cone of influence, the CDFG tool 230 traverses back through the flow-graph or netlist representation of the simulation to identify a signal that caused the detected X state failure. To expedite traversal through signals in the logical cone of influence, the CDFG tool 230 retrieves one or more rules from a traceback rule store 235. While FIG. 2 shows the traceback rule store 235 as a component of the CDFG tool 230, in other embodiments the traceback rule store 235 is a separate component that is accessed by the CDFG tool 230. The traceback rule store 235 includes one or more rules that are applied by the CDFG tool 230 to determine which path to choose when tracing back through the flow-graph or netlist representation of the simulation from detection of an X state failure. The rules streamline automatic traceback through the flow-graph or netlist representation to reduce an amount of time to identify a signal that caused the detected X state failure.

Example rules stored in the traceback rule store 235 include a rule to check clock signals for signals in the logical cone of influence, a rule to select a path of signals in the logical cone of influence that include the signal for which the X state failure was detected, a rule to select a path of signals in the logical cone of influence that crosses a voltage boundary, a rule to select a path of signals in the logical cone of influence that crosses a clock boundary, a rule to select a path of signals in the logical cone of influence that crosses a unit boundary, or a rule to select a path of signals in the logical cone of influence including one or more signals without an input source. In other embodiments, the traceback rule store includes rules specifying different criteria for selecting one or more signals from the logical cone of influence. Further, in some embodiments, rules included in the traceback rule store 235 are associated with simulation data loaded to the device being tested, allowing different traceback rules to be used for different simulations. In some embodiments, a set of rules are predefined for a set of simulation data. This allows the rules for tracing through a flow-graph or through a netlist of the simulation to be tailored to a specific simulation used for testing the device being tested, further reducing an amount of time to identify a signal that caused the X state failure detected by the monitoring module 225.

In some embodiments, in response to identifying the signal that caused the X state failure, the CDFG tool 230 modifies a breakpoint included in the breakpoint list 220 when the X state failure was detected. The CDFG tool 230 modifies the breakpoint to include the identified signal, with the modified breakpoint subsequently stored in the breakpoint store 210. As the breakpoint is associated with a state of the device being tested, modifying the breakpoint to include the identified signal allows subsequent testing using the simulation data to monitor the identified signal when the modified breakpoint is included in the breakpoint list 220. This allows a breakpoint to be dynamically modified to account for signals that caused an X state failure to be detected. In some embodiments, modifying the breakpoint also modifies a state of the device being tested based on tracing back through the flow-graph or the netlist of the simulation to include different or alternative values for latches or registers or to include values for an additional register or an additional latch.

Further, in response to identifying the signal that caused the X state failure, the CDFG tool 230, the CDFG tool 230 restarts the simulation applied to the device being tested in some embodiments. In other embodiments, after identifying the signal that caused the X state failure, the CDFG restarts the simulation applied to the device being tested from a starting point of the simulation.

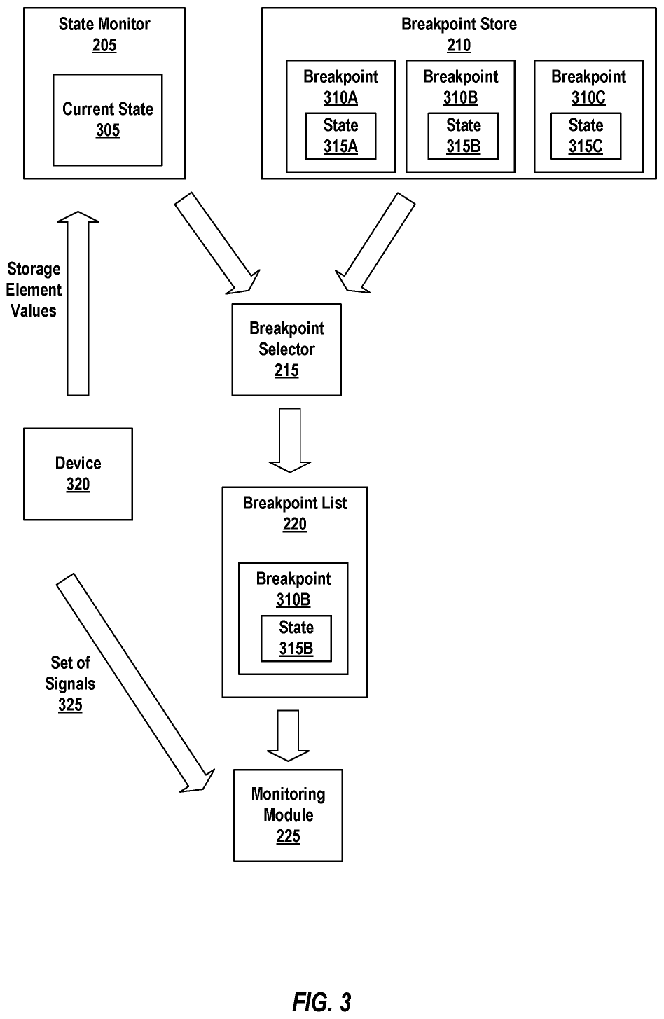

For further illustration, FIG. 3 shows a process flow diagram of the testing module 127 selecting a breakpoint list 220 to identify signals to monitor from a device being tested. In the example shown by FIG. 3, the state monitor 205 captures data from the device 320 being tested identifying values of different storage elements included in the device. For example, the state monitor 205 captures values of registers of the device or values of latches of the device 320. A combination of values of different storage elements included in the device 320 corresponds to a state of the device 320. As shown in FIG. 3, the state monitor 205 identifies a current state 305 of a device being tested based on values of the storage elements of the device at a current time. The current state 305 of the device 320 changes as values in the storage elements of the device 320 change. By monitoring the values of the storage elements of the device 320, the state monitor 205 identifies different states of the device 320 that correspond to times when the storage elements of the device have different values. In some embodiments, the state monitor 205 stores an identifier of a current state 305 of the device. For example, the state monitor 205 stores a combination of values of the storage elements of the device 320 at a current time as the current state 305. As another example, the state monitor 205 stores a state identifier that corresponds to a combination of values of the storage elements of the device 320 at the current time. In other embodiments, the state monitor 205 stores the current state 305 of the device 320 and one or more prior states of the device 320.

The breakpoint store 210 includes one or more breakpoints 310A-310C (also referred to individually and collectively using reference number 310). In various embodiments, the breakpoint store 210 includes a plurality of breakpoints 310A-310C. Each breakpoint 310 identifies a set of signals of the device being tested to be monitored. Different breakpoints 310A-310C identify different sets of signals in various embodiments. Each breakpoint 310A is associated with a state 315A-315C (also referred to individually and collectively using reference number 315) of the device being tested. In the example of FIG. 3, breakpoint 310A is associated with state 315A, breakpoint 310B is associated with state 315B, and breakpoint 310C is associated with state 315C. Different states 315 correspond to different combinations of values of storage elements of the device 320 being tested. Hence, different breakpoints 310 identify different sets of signals of the device being tested to monitor when the device 320 being tested is in different states 315. As further described above in conjunction with FIG. 2, this reduces a number of signals of the device being tested that are monitored at different times by identifying a set of signals based on a state of the device 320.

Based on the current state 305 of the device 320 being tested from the state monitor 205 and the states 315 associated with breakpoints from the breakpoint store 210, the breakpoint selector 215 selects a breakpoint list 220. The breakpoint list 220 includes one or more breakpoints 310 associated with states 315 that match the current state 305 of the device 320 being tested. In the example of FIG. 3, the current state 305 of the device 320 being tested matches state 315B, so the breakpoint selector 215 selects breakpoint 310B, which is associated with state 315B, for inclusion in the breakpoint list 220. While FIG. 3 shows a single breakpoint 310 included in the breakpoint list 220, in various embodiments, the breakpoint list 220 includes multiple breakpoints 310 that are each associated with a state 315 matching a current state of the device 320 being tested.

The monitoring module 225 obtains the breakpoint list 220 and monitors a set of signals 325 from the device 320 being tested that are specified by breakpoints 310 in the breakpoint list 220. In the example of FIG. 3, the set of signals 325 monitored by the monitoring module 225 are specified by breakpoint 310B, which is included in the breakpoint list 220. The set of signals 325 is less than a complete set of signals of the device 320 being tested in various embodiments, reducing the amount of data collected by the monitoring module 225 when testing the device 320. As the breakpoint list 220 includes one or more breakpoints 310 selected based on a state 315 of the device 320, as the state of the device 320 changes during testing, as the current state 305 of the device 320 changes, the breakpoints 310 included in the breakpoint list 220 change. This allows the breakpoint list 220 to be updated over time to change the set of signals 325 from the device 320 that are being monitored over time. This reduces the number of signals from the device 320 that are being monitored relative to conventional testing for X state failures, while continuing to monitor signals from the device 320 that are likely to be relevant to an X state failure.

As further described above in conjunction with FIG. 2, in response to the monitoring module 225 detecting an X state failure in one of the set of signals 325 being monitored, the monitoring module 225 suspends execution of a simulation that is testing the device 320. The monitoring module 225 also triggers a CDFG tool 230 to trace back through portions of the simulation that has been suspended to identify a signal that caused the detected X state failure. Suspending the simulation and back tracking through a portion of the simulation data allows the signal causing the X state failure to be detected more quickly than conventional methods that identify the X state failure, complete the simulation, then re-run the simulation to identify the signal that caused the X state failure. As further described above in conjunction with FIG. 2, the CDFG tool 230 includes a set of rules that are applied to select paths in a netlist or a flow-graph representation of the simulation when tracing back through the simulation, allowing tracing back through the simulation to be automated and to reduce an amount of time for tracing back through the simulation to identify the signal causing the X state failure.

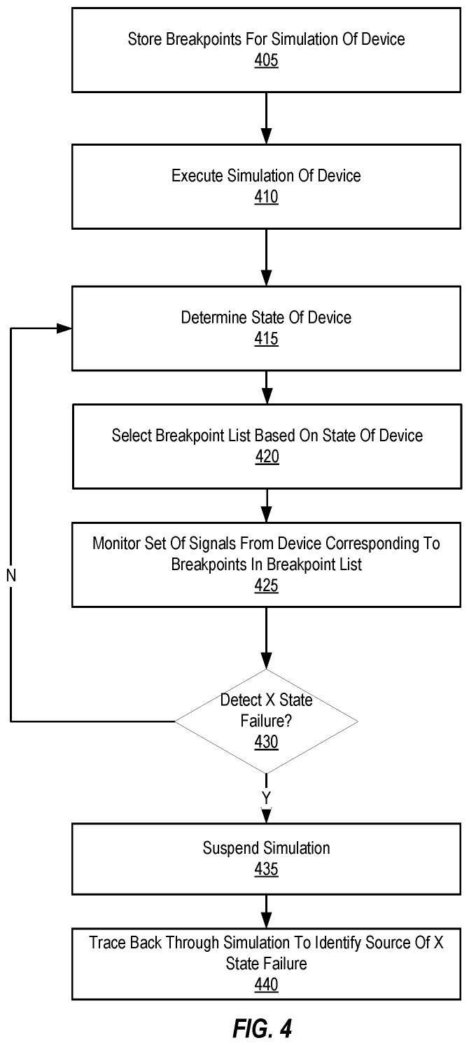

FIG. 4 is a flowchart of one embodiment of a method for detecting an X state failure when simulating a device according to embodiments of the present disclosure. In contrast to conventional methods for detecting a X state failure that monitor a complete set of signals from the device being tested, the method described in conjunction with FIG. 4 reduces a number of signals form the device that are monitored to a set of signals. Additionally, the method described in conjunction with FIG. 4 enables identification of a signal causing an X state failure without performing multiple iterations of a simulation testing the device.

A set of breakpoints for a simulation performed on a device are stored 405. For example, the set of breakpoints are stored in a breakpoint store 210, as further described above in conjunction with FIG. 2. Each breakpoint identifies one or more signals to be monitored. Additionally, each breakpoint is associated with a state of the device being tested. The state of the device being tested is based on values stored by storage elements of the device. For example, a state of the device corresponds to a value in a combination of registers (or latches) in the device. Different breakpoints are associated with different states of the device in various embodiments. Associating different breakpoints with different states of the device allows different sets of signals from the device to be monitored when the device is in different states. This allows the signals being monitored to be dynamically changed during simulation of the device as the state of the device changes.

With the set of breakpoints stored 405, a simulation is executed 410 by the device. The simulation is a multi-valued simulation in various embodiments. The simulation is based on one or more models and simulates operation of the device. For example, a simulation simulates a sequence of actions performed by the device when the device is initially powered on. Different simulations simulate different steps in initializing the device or operating the device in various embodiments. In various embodiments, the breakpoints that are stored 410 are associated with the simulation. This allows different breakpoints to be specified for different simulations, allowing different sets of signals from the device to be tailored to a particular simulation by storing 405 breakpoints associated with the particular simulation.

As the simulation is executed 410, storage elements of the device are monitored. Values of the storage elements are used to determine 415 a state of the device being tested. Different combinations of values in storage elements of the device correspond to different states of the device. As the values in the storage elements of the device change, the state of the device changes. Thus, the state of the device changes as the simulation is executed 410, reflecting changes to the device occurring during simulation.

Based on the state of the device determined 415 from the values of the storage elements of the device, a breakpoint list 220 is selected 420 from the stored breakpoints. The breakpoint list 220 includes one or more stored breakpoints that are associated with a state matching the determined state of the device. In some embodiments, the breakpoint list 220 includes each breakpoint associated with a set matching the determined state of the device. As a breakpoint specifies a set of signals of the device, signals identified by the breakpoints selected 420 for the breakpoint list 220 are monitored 425. Because breakpoints are selected 420 for the breakpoint list 220 based on the state of the device, the set of signals from the device that are monitored 420 is determined based on the state of the device. As the determined state of the device changes, the breakpoints selected 415 for the breakpoint list 220 change, which changes the set of signals that are monitored 425. As further described above in conjunction with FIGS. 2 and 3, the set of signals from the device being monitored 425 is less than a complete set of signals from the device. Hence, selecting 420 breakpoints for the breakpoint list 420 based on the state of the device reduces a number of signals that are monitored 425, while maintaining monitoring 425 of signals likely to be relevant to an X state failure during the determined state of the device.

While the set of signals corresponding to the breakpoints in the breakpoint list 220 are being monitored 425, the method determines 430 whether a transition from a defined value to an undefined value, an “X state failure,” is detected on at least one signal of the set of signals. When no X state failure is determined 430 to be detected, the state of the device is determined 415 and used to select 420 the breakpoint list, as further described above. This allows the state of the device to be dynamically determined 415 during execution of the simulation, so the state of the device changes based on the simulation. When the state of the device changes, the breakpoint list 220 is updated based on the changed state of the device. This causes the set of signals that are monitored 425 to be updated when the breakpoint list 220 is updated. Thus, the method described in conjunction with FIG. 4 dynamically modifies the set of signals that are monitored 425 as a state of the device changes, allowing fewer signals to be monitored 425 than conventional testing, while monitoring 425 signals that are most likely to be relevant to identifying an X state failure.

However, in response to determining 430 an X state failure is detected for a signal of the set of signals that are monitored 425, the method suspends 435 the simulation. In contrast, conventional techniques for testing continue the simulation to completion after detection of an X state failure. As an X state failure may initially occur early in a simulation but not be observed until later in the simulation, suspending 435 the simulation once the X state failure is detected reduces an amount of data to be analyzed to identify when then X state failure occurred.

With the simulation suspended 435, the method traces back 440 through the simulation from when the X state failure was determined 430 to identify a source that caused the X state failure. In various embodiments, a CDFG tool 230, as further described above in conjunction with FIG. 2, is used to trace back 440 through the simulation. The CDFG tool 230 obtains a netlist or a flow-graph representation of the simulation that describes control and data flow information through the simulation being performed to test the device being tested. The representation obtained by the CDFG tool 230 describes data dependencies and control dependencies between different registers of a device throughout the simulation. When an X state failure is detected and the simulation is suspended 435, the CDFG tool 230 traces back 440 through representation of the simulation from a time when the X state failure was detected to identify signals related to the X state failure and to identify a signal that caused the X state failure. For example, the CDFG tool 230 obtains a logical cone of influence for the X state failure by tracing back 440 through the representation of the simulation from the X state failure. The logical cone of influence includes a listing of signals that are related to the signal where the X state failure was detected. Signals in the logical cone of influence are signals that are related to or that influence a value of the signal for which the X state failure was detected.

To more efficiently trace back 440 through the representation of the simulation from the X state failure, the method retrieves one or more retrieves one or more rules from a traceback rule store 235. As further described above in conjunction with FIG. 2, the one or more rules determine which path to choose when tracing back 440 through the representation of the simulation from when an X state failure was detected. The rules streamline automatic tracing back 440 through the representation to reduce an amount of time to identify a signal that caused the detected X state failure. For example, one or more rules identify characteristics of a path through the representation selected to be traced back 440 through. The rules allow the CDFG tool 230 to automatically select a path through the representation of the simulation to traverse to identify a signal causing the detected X state failure. In some embodiments, the rules specify an order in which paths through the representation of the simulation are selected, with a first rule specifying criteria for initial selection of a path through the representation of the simulation. If the signal causing the detected X state failure is not identified when traversing the initially selected path, an alternative path is selected based on criteria specified by another rule and is traversed. Such embodiments allow the rules in the traceback rule store 235 to simplify tracing through a representation of the simulation by identifying criteria for selecting one or more paths to traverse through the representation of the simulation. The rules in the traceback rule store 235 simplify automatic selection of a path through the representation of the simulation when multiple paths are available to travel through the representation of the simulation, reducing an amount of time for tracing back 440 through the simulation without manual input.

In some embodiments, in response to identifying the signal that caused the X state failure, the method modifies a breakpoint included in the breakpoint list 220 when the X state failure was detected to include the identified signal. The modified breakpoint is subsequently stored in the breakpoint store 210. As the breakpoint is associated with a state of the device, modifying the breakpoint to include the identified signal allows subsequent testing using the simulation to monitor the identified signal when the modified breakpoint is included in the breakpoint list 220. This allows dynamic modification of a breakpoint for monitoring 425 the signal identified when the X state failure was detected, enabling subsequent simulations to more quickly identify the X state failure that was detected. In some embodiments, modifying the breakpoint also modifies a state of the device being tested based on tracing back through the flow-graph or the netlist of the simulation to include different or alternative values for latches or registers or to include values for an additional register or an additional latch.

Storing a set of breakpoints that are each associated with a state of the device being tested allows more efficient monitoring of signals when testing for an X state failure. Rather than monitoring a complete set of signals from the device, the set of breakpoints limits monitoring to a set of signals associated with a state of the device. As different states are associated with different sets of signals, the set of signals being monitored is dynamically modified as the state of the device changes, allowing signals relevant to an X state failure for different states of the device to be monitored. Additionally, suspending a simulation when an X state failure is detected and tracing back through the simulation allows a source of the X state failure to be determined without performing multiple iterations of the simulation. Storing rules for tracing back through the simulation allows automatic traversal of the simulation to identify a signal that caused a detected X state failure, reducing an amount of time to identify the cause of a detected X state failure compared to conventional methods that manually traverse backwards through the simulation from detection of the X state failure. Further, the method described herein allows a breakpoint to be dynamically updated when an X state failure is detected to subsequently identify a signal determined to have caused the X state failure, allowing carlier monitoring and identification of the signal for an X state failure in subsequent simulations.

Exemplary embodiments of the present invention are described largely in the context of a fully functional computer system for performing a context switch by replacing an address translation context used by the computer processor. Readers of skill in the art will recognize, however, that the present invention also may be embodied in a computer program product disposed upon computer readable storage media for use with any suitable data processing system. Such computer readable storage media may be any storage medium for machine-readable information, including magnetic media, optical media, or other suitable media. Examples of such media include magnetic disks in hard drives or diskettes, compact disks for optical drives, magnetic tape, and others as will occur to those of skill in the art. Persons skilled in the art will immediately recognize that any computer system having suitable programming means will be capable of executing the steps of the method of the invention as embodied in a computer program product. Persons skilled in the art will recognize also that, although some of the exemplary embodiments described in this specification are oriented to software installed and executing on computer hardware, nevertheless, alternative embodiments implemented as firmware or as hardware are well within the scope of the present invention.

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. A method for identifying a transition of a signal from a defined state to an undefined state when simulating a device, the method comprising:
storing a set of breakpoints, each breakpoint associated with a state of the device and identifying a set of signals from the device;
executing a simulation of the device using simulation data;
determining a current state of the device from values of one or more storage elements of the device;
selecting a breakpoint list including one or more breakpoints based on the current state of the device; and
monitoring the set of signals from the device identified by the one or more breakpoints included in the breakpoint list.

2. The method of claim 1, wherein selecting the breakpoint list including one or more breakpoints based on the current state of the device comprises:
selecting one or more breakpoints each associated with a state of the device matching the current state of the device.

3. The method of claim 1, further comprising:
responsive to detecting the transition from the defined state to the undefined state on a signal included in the set of signals identified by the one or more breakpoints included in the breakpoint list, suspending execution of the simulation.

4. The method of claim 3, further comprising:
tracing back through the simulation from a time when the transition from the defined state to the undefined state was detected to identify a source of the transition from the defined state to the undefined state.

5. The method of claim 4, wherein tracing back through the simulation from the time when the transition from the defined state to the undefined state comprises:
retrieving a representation of the simulation;
retrieving one or more rules determining determine which path to choose when tracing back through the representation of the simulation; and
selecting a path for tracing back through the simulation based on the one or more rules.

6. The method of claim 4, further comprising:
responsive to identifying the source of the transition from the defined state to the undefined state, modifying a breakpoint included in the breakpoint list to include the identified source.

7. The method of claim 6, further comprising:
storing the modified breakpoint.

8. The method of claim 1, further comprising:
determining an updated state of the device from values of one or more storage elements of the device;
selecting an updated breakpoint list including one or more updated breakpoints based on the updated state of the device; and
monitoring the set of signals from the device identified by the one or more updated breakpoints included in the updated breakpoint list.

9. An apparatus for identifying a transition of a signal from a defined state to an undefined state when simulating a device, the apparatus comprising a computer processor, a computer memory operatively coupled to the computer processor, the computer memory having disposed within it computer program instructions that, when executed by the computer processor, cause the apparatus to carry out steps of:
storing a set of breakpoints, each breakpoint associated with a state of the device and identifying a set of signals from the device;
executing a simulation of the device using simulation data;
determining a current state of the device from values of one or more storage elements of the device;
selecting a breakpoint list including one or more breakpoints based on the current state of the device; and
monitoring the set of signals from the device identified by the one or more breakpoints included in the breakpoint list.

10. The apparatus of claim 9, wherein selecting the breakpoint list including one or more breakpoints based on the current state of the device comprises:
selecting one or more breakpoints each associated with a state of the device matching the current state of the device.

11. The apparatus of claim 9, wherein the computer memory further has disposed within it computer program instructions that, when executed by the computer processor, cause the apparatus to carry out steps comprising:
responsive to detecting the transition from the defined state to the undefined state on a signal included in the set of signals identified by the one or more breakpoints included in the breakpoint list, suspending execution of the simulation.

12. The apparatus of claim 11, wherein the computer memory further has disposed within it computer program instructions that, when executed by the computer processor, cause the apparatus to carry out steps comprising:
tracing back through the simulation from a time when the transition from the defined state to the undefined state was detected to identify a source of the transition from the defined state to the undefined state.

13. The apparatus of claim 12, wherein tracing back through the simulation from the time when the transition from the defined state to the undefined state comprises:
retrieving a representation of the simulation;
retrieving one or more rules determining determine which path to choose when tracing back through the representation of the simulation; and
selecting a path for tracing back through the simulation based on the one or more rules.

14. The apparatus of claim 12, wherein the computer memory further has disposed within it computer program instructions that, when executed by the computer processor, cause the apparatus to carry out steps comprising:
responsive to identifying the source of the transition from the defined state to the undefined state, modifying a breakpoint included in the breakpoint list to include the identified source.

15. A computer program product for identifying a transition of a signal from a defined state to an undefined state when simulating a device, the computer program product disposed upon a computer readable medium, the computer program product comprising computer program instructions that, when executed, cause a computer to carry out steps of:
storing a set of breakpoints, each breakpoint associated with a state of the device and identifying a set of signals from the device;
executing a simulation of the device using simulation data;
determining a current state of the device from values of one or more storage elements of the device;
selecting a breakpoint list including one or more breakpoints based on the current state of the device; and
monitoring the set of signals from the device identified by the one or more breakpoints included in the breakpoint list.

16. The computer program product of claim 15, wherein selecting the breakpoint list including one or more breakpoints based on the current state of the device comprises:
selecting one or more breakpoints each associated with a state of the device matching the current state of the device.

17. The computer program product of claim 15, further comprising computer program instructions that, when executed, cause the computer to carry out steps of:
responsive to detecting the transition from the defined state to the undefined state on a signal included in the set of signals identified by the one or more breakpoints included in the breakpoint list, suspending execution of the simulation.

18. The computer program product of claim 17, further comprising computer program instructions that, when executed, cause the computer to carry out steps of:
tracing back through the simulation from a time when the transition from the defined state to the undefined state was detected to identify a source of the transition from the defined state to the undefined state.

19. The computer program product of claim 18, wherein tracing back through the simulation from the time when the transition from the defined state to the undefined state comprises:
retrieving a representation of the simulation;
retrieving one or more rules determining determine which path to choose when tracing back through the representation of the simulation; and
selecting a path for tracing back through the simulation based on the one or more rules.

20. The computer program product of claim 18, further comprising computer program instructions that, when executed, cause the computer to carry out steps of:
responsive to identifying the source of the transition from the defined state to the undefined state, modifying a breakpoint included in the breakpoint list to include the identified source.
